(19) United States
(12) Patent Application Publication
(10) Pub. No.: US 2026/0090400 A1
(43) Pub. Date: Mar. 26, 2026

(54) SEMICONDUCTOR DEVICE AND METHOD OF MANUFACTURING THE SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hiroshi KADONO, Ibo Hyogo (JP)

(21) Appl. No.: 19/047,087

(22) Filed: Feb. 6, 2025

(30) Foreign Application Priority Data
Sep. 20, 2024 (JP) 2024-163645

(51) Int. Cl. H01L 23/495; H01L 21/48; H01L 23/00; H01L 23/31; H01L 25/07

(52) U.S. Cl. CPC H10W 70/421; H10W 70/042; H10W 70/458; H10W 90/00; H10W 72/07554; H10W 74/111; H10W 90/755

(57) ABSTRACT

According to one embodiment, a semiconductor device includes first and second frames, a first semiconductor chip, a wire, and a resin. The second frame is arranged so as to face the first frame in a first direction, and has a stepped portion on an end portion of an upper surface. The first semiconductor chip is arranged on a bottom surface of the stepped portion. The wire electrically couples the first semiconductor chip and the first frame. The resin covers part of each of the first and second frames and seals the first semiconductor chip and the wire. A lower surface of the first frame and a side surface of the first frame in the first direction are exposed from the resin. A lower surface of the second frame and a side surface of the second frame in the first direction are exposed from the resin.

### CROSS-REFERENCE TO RELATED APPLICATIONS

This application is based upon and claims the benefit of priority from Japanese Patent Application No. 2024-163645, filed Sep. 20, 2024, the entire contents of which are incorporated herein by reference.

### FIELD

Embodiments described herein relate generally to a semiconductor device and a method of manufacturing the semiconductor device.

### BACKGROUND

A semiconductor device including a lead frame equipped with a semiconductor element is known.

### BRIEF DESCRIPTION OF THE DRAWINGS

FIG. 1 is a perspective view showing an example of an external shape of a semiconductor device according to a first embodiment.

FIG. 2 is a perspective view showing an example of the external shape of the semiconductor device according to the first embodiment.

FIG. 3 is a perspective view showing an example of a structure of the semiconductor device according to the first embodiment.

FIG. 4 is a planar view showing an example of the structure of the semiconductor device according to the first embodiment.

FIG. 5 is a planar view showing an example of the structure of the semiconductor device according to the first embodiment.

FIG. 6 is a cross-sectional view showing an example of the structure of the semiconductor device according to the first embodiment.

FIG. 7 is a cross-sectional view showing a structure of an implementation example of the semiconductor device according to the first embodiment.

FIG. 8 is a flowchart showing an example of a method of manufacturing the semiconductor device according to the first embodiment.

FIG. 9 is a diagram showing steps in the method of manufacturing the semiconductor device according to the first embodiment.

FIG. 10 is a diagram showing a step in the method of manufacturing the semiconductor device according to the first embodiment.

FIG. 11 is a diagram showing a step in the method of manufacturing the semiconductor device according to the first embodiment.

FIG. 12 is a diagram showing a step in the method of manufacturing the semiconductor device according to the first embodiment.

FIG. 13 is a diagram showing a step in the method of manufacturing the semiconductor device according to the first embodiment.

FIG. 14 is a diagram showing a step in the method of manufacturing the semiconductor device according to the first embodiment.

FIG. 15 is a diagram showing a step in the method of manufacturing the semiconductor device according to the first embodiment.

FIG. 16 is a perspective view showing an example of a structure of a semiconductor device according to a second embodiment.

FIG. 17 is a planar view showing an example of the structure of the semiconductor device according to the second embodiment.

FIG. 18 is a planar view showing an example of the structure of the semiconductor device according to the second embodiment.

FIG. 19 is a flowchart showing an example of a method of manufacturing the semiconductor device according to the second embodiment.

FIG. 20 is a planar view showing an example of a structure of a semiconductor device according to a third embodiment.

FIG. 21 is a planar view showing an example of the structure of the semiconductor device according to the third embodiment.

FIG. 22 is a cross-sectional view showing an example of the structure of the semiconductor device according to the third embodiment.

FIG. 23 is a planar view showing an example of a structure of a semiconductor device according to a fourth embodiment.

FIG. 24 is a planar view showing an example of the structure of the semiconductor device according to the fourth embodiment.

### DETAILED DESCRIPTION

In general, according to one embodiment, a semiconductor device includes a first frame, a second frame, a first semiconductor chip, a wire, and a resin. The second frame is arranged so as to face the first frame in a first direction, and has a stepped portion on an end portion of an upper surface, the end portion being closer to the first frame. The first semiconductor chip is arranged on a bottom surface of the stepped portion of the second frame. The wire provides electrical coupling between the first semiconductor chip and the first frame. The resin covers part of each of the first frame and the second frame and seals the first semiconductor chip and the wire. A lower surface of the first frame and a first side surface of the first frame, the first side surface being far from the second frame in the first direction, are exposed from the resin. A lower surface of the second frame and a second side surface of the second frame, the second side surface being far from the first frame in the first direction, are exposed from the resin.

Hereinafter, embodiments will be described with reference the accompanying drawings. The dimensions and ratios in the drawings are not always the same as the actual ones. In the following description, constituent elements having substantially the same function and configuration will be assigned the same reference numeral or symbol and repeat descriptions may be omitted. In the case where elements having similar configurations are distinguished from each other in particular, their identical reference symbols may be assigned different letters or numbers. All of the descriptions of an embodiment are applicable as descriptions of another embodiment, unless explicitly or self-evidently excluded.

### 1. First Embodiment

A semiconductor device according to a first embodiment will be described. Hereinafter, a semiconductor device having a wettable flank (WF) structure will be described as an example. The semiconductor device according to the present embodiment is applied to, for example, an on-vehicle semiconductor package.

### 1.1 Structure of Semiconductor Device

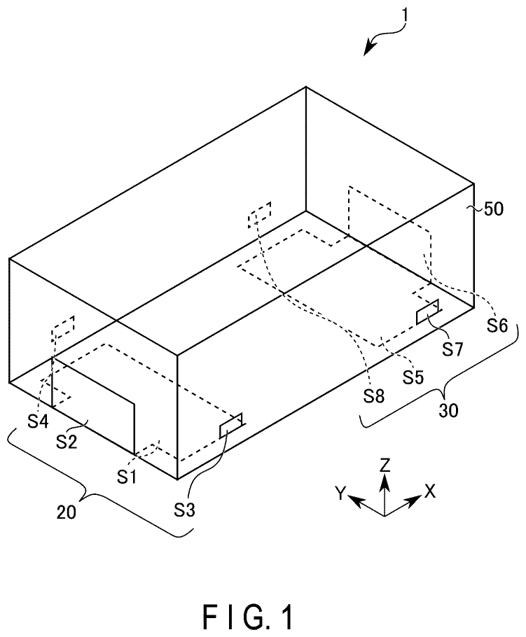

First, a structure of the semiconductor device will be described with reference to FIG. 1 to FIG. 6. A semiconductor device 1 includes a semiconductor element, a lead frame and a bonding wire, and has a package structure in which the semiconductor element and the bonding wire is sealed with a package member.

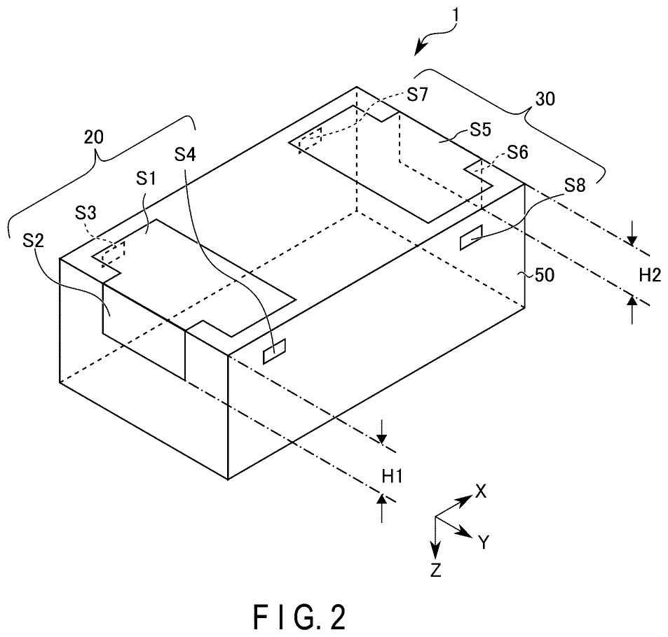

FIG. 1 and FIG. 2 are each a perspective view showing an example of an external shape of the semiconductor device 1. FIG. 1 shows a structure of the semiconductor device 1 as viewed from an upper surface side. FIG. 2 shows a structure of the semiconductor device 1 as viewed from a lower surface side.

As shown in FIG. 1 and FIG. 2, the semiconductor device 1 includes lead frames 20 and 30 and a package member 50.

The lead frame 20 has surfaces exposed from the package member 50, that is, a first surface (lower surface) S1, a second surface (side surface) S2, a third surface S3, and a fourth surface S4. The first surface S1 is in contact with the second surface S2. The second surface S2 has a height H1. The height H1 is, for example, 150 μm or greater and 200 μm or smaller. The third surface S3 faces the fourth surface S4. The first surface S1 and the second surface S2 correspond to terminals (electrodes) of the lead frame 20. The first surface S1 and the second surface S2 function as external connection terminals coupled to an outside. The third surface S3 and the fourth surface S4 are each a suspension pin. The suspension pin is a connecting portion for connecting, in a state in which the lead frames 20 and 30 are in a lead frame base member in manufacturing, a part to be formed as the lead frame 20 to a part to be formed as the lead frame 30. In manufacturing, the lead frame 20 is separated from the lead frame base member through dicing to be described later. Surfaces cut through dicing of the suspension pins correspond to the third surface S3 and the fourth surface S4.

The lead frame 30 has surfaces exposed from the package member 50, that is, a fifth surface (lower surface) S5, a sixth surface (side surface) S6, a seventh surface S7, and an eighth surface S8. The fifth surface S5 is in contact with the sixth surface S6. The sixth surface S6 has a height H2. The height H2 is substantially equal to the height H1. The height H2 is, for example, 150 μm or greater and 200 μm or smaller. The seventh surface S7 faces the eighth surface S8. The fifth surface S5 and the sixth surface S6 correspond to terminals (electrodes) of the lead frame 30. The fifth surface S5 and the sixth surface S6 function as external connection terminals coupled to an outside. The seventh surface S7 and the eighth surface S8 are each a suspension pin. In manufacturing, the lead frame 30 is separated from the lead frame base member through dicing. Surfaces cut through dicing of the suspension pins correspond to the seventh surface S7 and the eighth surface S8.

Hereinafter, the height H1 of the second surface S2 and the height H2 of the sixth surface S6 will be also referred to as a “WF length”.

The lower surface of the semiconductor device 1 is a surface in which the terminal (first surface S1) of the lead frame 20 and the terminal (fifth surface S5) of the lead frame 30 are exposed from the package member 50, and is a so-called implementation surface of the semiconductor device 1, through which the semiconductor device 1 is implemented on a main substrate.

The following description will use an orthogonal coordinate system consisting of an X axis, a Y axis, and a Z axis. An X direction is parallel to the surface of the lead frame 20 and corresponds to, for example, a direction from the lead frame 20 to the lead frame 30. A Y direction is parallel to the surface of the lead frame 20 and corresponds to, for example, a direction from the third surface S3 of the lead frame 20 to the fourth surface S4 of the lead frame 20. A Z direction is perpendicular to the surface of the lead frame 20 and corresponds to a vertical direction. The term “up” and its derivative and related terms refer to a position at a larger coordinate on the Z axis and the term “low” and its derivative and related terms refer to a position at a smaller coordinate on the Z axis.

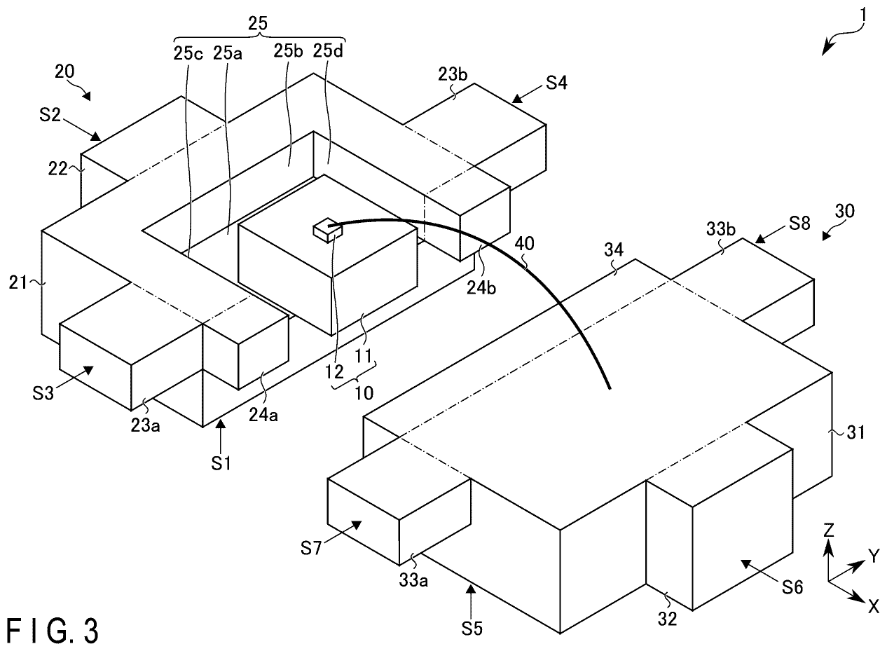

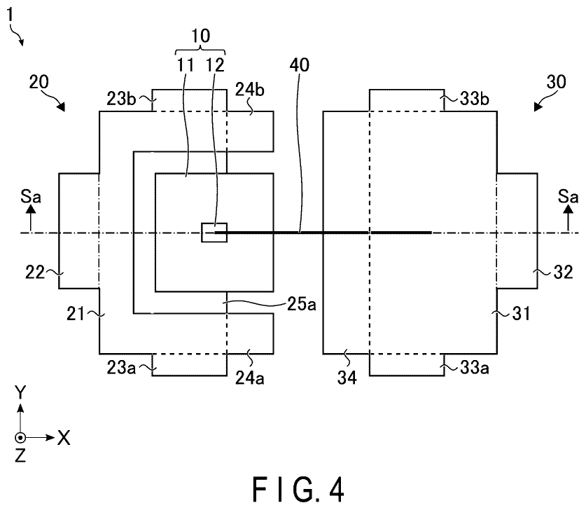

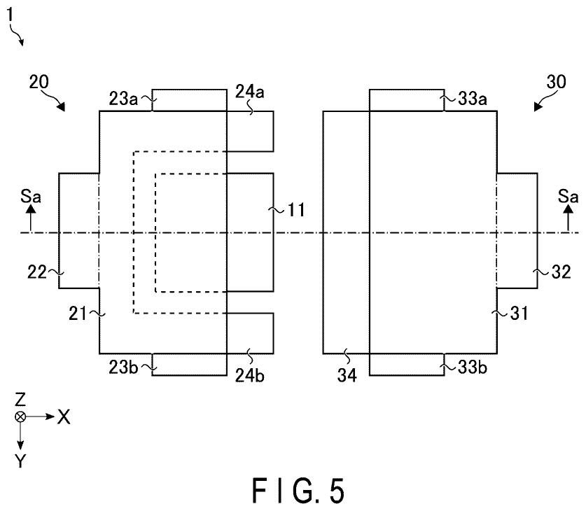

FIG. 3 is a perspective view showing an example of a structure of the semiconductor device 1. FIG. 3 shows a structure of the semiconductor device 1 as viewed from the upper surface side with the package member 50 being transparent in FIG. 1. FIG. 4 and FIG. 5 are each a planar view showing an example of the structure of the semiconductor device 1. FIG. 4 shows a structure of the semiconductor device 1 as viewed from the upper surface side with the package member 50 being transparent in FIG. 1. FIG. 5 shows a structure of the semiconductor device 1 as viewed from the lower surface side with the package member 50 being transparent in FIG. 2.

As shown in FIG. 3 to FIG. 5, the semiconductor device 1 includes the semiconductor element (semiconductor chip) 10, the lead frames 20 and 30, and a bonding wire 40.

Examples of the semiconductor element 10 include a diode, a field effect transistor, a bipolar transistor, or an insulated gate bipolar transistor (IGBT). Hereinafter, a case in which the semiconductor element 10 is a diode will be described as an example.

The semiconductor element 10 is, for example, a semiconductor chip (or a bare chip, a die). The semiconductor element 10 includes an element portion 11 and a pad (or a node, a terminal) 12.

The element portion 11 includes, for example, a semiconductor layer on which a diode is formed. The semiconductor layer is, for example, silicon, silicon carbide, silicon germanium, gallium nitride, or gallium arsenide.

The pad 12 is provided on the upper surface of the element portion 11. The pad 12 is electrically coupled to an anode (not shown) of the semiconductor element 10 via a conductive member (not shown) formed by curing a conductive paste, for example. The pad 12 includes a metal layer such as aluminum or copper, for example. The pad 12 may be electrically coupled to a cathode of the semiconductor element 10 according to the internal structure of the element portion 11.

The lead frame 20 includes a base portion 21 and projecting portions 22, 23a, 23b, 24a, and 24b.

The base portion 21 is formed into substantially a rectangular parallelepiped shape and has a part (hereinafter referred to as a “stepped portion 25”) in which an upper surface is partially concaved. That is, the base portion 21 includes the stepped portion 25 on its upper surface.

Each of the projecting portions 22, 23a, 23b, 24a, and 24b is formed into, for example, substantially a rectangular parallelepiped shape. Each of the projecting portions 22, 23a, 23b, 24a, and 24b is a part projecting from the base portion 21. In other words, each of the projecting portions 22, 23a, 23b, 24a, and 24b is in contact with the base portion 21.

The projecting portion 22 projects from a side surface which is one of the side surfaces of the base portion 21 in the X direction and is located far from the lead frame 30. The projecting portion 22 is equal in height to, for example, the base portion 21. The projecting portion 23a projects from one of the two side surfaces of the base portion 21 in the Y direction. The projecting portion 23b projects from the other one of the two side surfaces of the base portion 21 in the Y direction. The projecting portions 23a and 23b are spaced apart from each other and face each other in the Y direction. The projecting portions 23a and 23b are each, for example, smaller in height than the base portion 21. The projecting portion 23a is equal in height to, for example, the projecting portion 23b. Each of the projecting portions 24a and 24b projects from a side surface which is one of the side surfaces of the base portion 21 in the X direction and is closer to the lead frame 30. The projecting portions 24a and 24b are spaced apart from each other and face each other in the Y direction. The projecting portions 24a and 24b are each, for example, smaller in height than the base portion 21. The projecting portion 24a is equal in height to, for example, the projecting portions 23a, 23b, and 24b.

The lower surface of the base portion 21 and the lower surface of the projecting portion 22 correspond to the first surface S1. Of the plurality of side surfaces of the projecting portion 22, a side surface not in contact with the base portion 21 in the X direction corresponds to the second surface S2. The height of the projecting portion 22 corresponds to the height H1 of the second surface S2. Of the plurality of side surfaces of the projecting portion 23a, a side surface not in contact with the base portion 21 in the Y direction corresponds to the third surface S3. Of the plurality of side surfaces of the projecting portion 23b, a side surface not in contact with the base portion 21 in the Y direction corresponds to the fourth surface S4.

The stepped portion 25 is provided on the upper surface of the base portion 21. More specifically, the stepped portion 25 is provided at an end portion of the upper surface of the base portion 21, which is closer to the lead frame 30. The stepped portion 25 is formed into, for example, a substantially rectangular shape as viewed from the upper surface side. The stepped portion 25 includes a bottom surface 25a and side walls 25b, 25c, and 25d. The bottom surface 25a and the side walls 25b, 25c, and 25d are included in the base portion 21. The bottom surface 25a is used as an external connection terminal and functions as a mount portion on which the semiconductor element 10 is to be mounted.

The lead frame 30 includes a base portion 31 and projecting portions 32, 33a, 33b, and 34.

The base portion 31 is formed into, for example, a substantially rectangular parallelepiped shape.

Each of the projecting portions 32, 33a, 33b, and 34 is formed into, for example, substantially a rectangular parallelepiped shape. Each of the projecting portions 32, 33a, 33b, and 34 is a portion projecting from the base portion 31. In other words, each of the projecting portions 32, 33a, 33b, and 34 is in contact with the base portion 31.

The projecting portion 32 projects from a side surface which is one of the side surfaces of the base portion 31 in the X direction and is located far from the lead frame 20. The projecting portion 32 is equal in height to, for example, the base portion 31. The projecting portion 33a projects from one of the two side surfaces of the base portion 31 in the Y direction. The projecting portion 33b projects from the other one of the two side surfaces of the base portion 31 in the Y direction. The projecting portions 33a and 33b are spaced apart from each other and face each other in the Y direction. The projecting portions 33a and 33b are each, for example, smaller in height than the base portion 31. The projecting portion 33a is equal in height to, for example, the projecting portion 33b. The projecting portion 34 projects from a side surface which is one of the side surfaces of the base portion 31 in the X direction and is closer to the lead frame 20. The projecting portion 34 is, for example, smaller in height than the base portion 31 and is equal in height to each of the projecting portions 33a and 33b.

The lower surface of the base portion 31 and the lower surface of the projecting portion 32 correspond to the fifth surface S5. Of the plurality of side surfaces of the projecting portion 32, a side surface not in contact with the base portion 31 in the X direction corresponds to the sixth surface S6. The height of the projecting portion 32 corresponds to the height H2 of the sixth surface S6. Of the plurality of side surfaces of the projecting portion 33a, a side surface not in contact with the base portion 31 in the Y direction corresponds to the seventh surface S7. Of the plurality of side surfaces of the projecting portion 33b, a side surface not in contact with the base portion 31 in the Y direction corresponds to the eighth surface S8.

The lead frames 20 and 30 are spaced apart from each other and face each other in the X direction.

The semiconductor element 10 is provided on the bottom surface 25a of the stepped portion 25. Part of the semiconductor element 10 faces the lead frame 20. The stepped portion 25 has the side wall 25b in the X direction. The stepped portion 25 has the side walls 25c and 25d facing each other in the Y direction. Three side surfaces of the semiconductor element 10 are surrounded by the side walls 25b, 25c, and 25d of the stepped portion 25. The bottom surface 25a of the stepped portion 25 is electrically coupled to a cathode (not shown) of the semiconductor element 10 via a conductive member (not shown) formed by curing a conductive paste, for example. The bottom surface 25a of the stepped portion 25 may be electrically coupled to an anode of the semiconductor element 10 according to the internal structure of the element portion 11.

One end of the bonding wire 40 is coupled to the upper surface of the pad 12. The other end of the bonding wire 40 is coupled to the upper surface of the base portion 31 of the lead frame 30. The bonding wire 40 provides electrical coupling between the pad 12 of the semiconductor element 10 and the base portion 31 of the lead frame 30.

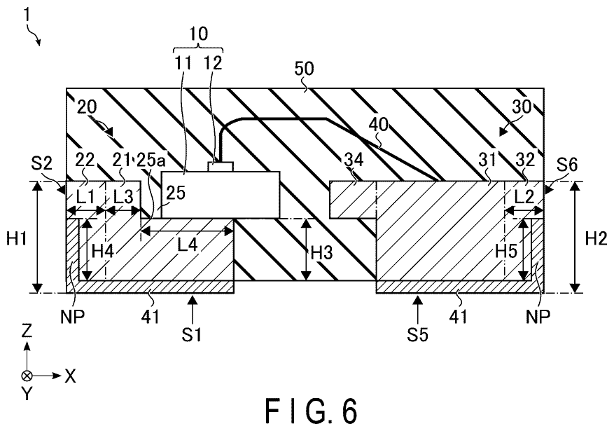

FIG. 6 is a cross-sectional view showing an example of a structure of the semiconductor device 1. FIG. 6 shows a cross-sectional structure of the semiconductor device 1 taken along the line Sa-Sa in FIG. 4 and FIG. 5.

As shown in FIG. 6, the package member (or a sealing member, a resin body, a mold resin, a package resin) 50 is provided on the semiconductor element 10, the lead frame 20, and the lead frame 30. The package member 50 covers a portion of each of the lead frames 20 and 30, covers the semiconductor element 10 placed on the bottom surface 25a of the stepped portion 25 of the lead frame 20, thereby sealing the semiconductor element 10 and the bonding wire 40. The package member 50 is provided in a space surrounded by the semiconductor element 10 and the lead frames 20 and 30. The package member 50 is an insulator and includes, for example, an insulating resin or ceramics, and polyimide.

The projecting portion 22 of the lead frame 20 has a notch portion NP at an end portion at a side of the lower surface, not in contact with the base portion 21. The lower surface of the base portion 21 of the lead frame 20, the lower surface of the projecting portion 22 of the lead frame 20, and the notch portion NP of the projecting portion 22 are provided with a plating layer 41. The plating layer 41 includes, for example, tin or solder. Hereinafter, the lower surface of the plating layer 41 in contact with the base portion 21 and the projecting portion 22 will be referred to as the first surface S1 of the lead frame 20. In the lead frame 20, a side surface at a side not in contact with the base portion 21 of the projecting portion 22 and a side surface at a side not in contact with the projecting portion 22 of the plating layer 41 will be referred to as the second surface S2 of the lead frame 20. The first surface S1 and the second surface S2 of the lead frame 20 are exposed from the package member 50. The height H1 of the second surface S2 of the lead frame 20 is the height from the lower surface of the plating layer 41 to the upper surface of the projecting portion 22 of the lead frame 20.

The projecting portion 32 of the lead frame 30 has a notch portion NP at an end portion at a side of the lower surface, not in contact with the base portion 31. The lower surface of the base portion 31 of the lead frame 30, the lower surface of the projecting portion 32 of the lead frame 30, and the notch portion NP of the projecting portion 32 are provided with a plating layer 41. Hereinafter, the lower surface of the plating layer 41 in contact with the base portion 31 and the projecting portion 32 will be referred to as the fifth surface S5 of the lead frame 30. In the lead frame 30, a side surface at a side not in contact with the base portion 31 of the projecting portion 32 and a side surface at a side not in contact with the projecting portion 32 of the plating layer 41 will be referred to as the sixth surface S6 of the lead frame 30. The fifth surface S5 and the sixth surface S6 of the lead frame 30 are exposed from the package member 50. The height H2 of the sixth surface S6 of the lead frame 30 is the height from the lower surface of the plating layer 41 to the upper surface of the projecting portion 32 of the lead frame 30.

As described above, in the semiconductor device 1, each of the terminals (the first surface S1 and the second surface S2) of the lead frame 20 and the terminals (the fifth surface S5 and the sixth surface S6) of the lead frame 30 has a WF structure.

The height H3 from the lower surface of the lead frame 20 to the bottom surface 25a of the stepped portion 25 of the lead frame 20 (hereinafter referred to as a “height H3 of the stepped portion 25”) is designed in consideration of, for example, the thickness of the semiconductor element 10. The height H3 of the stepped portion 25 is smaller than the height H1. That is, the height H3 is different from the height H1. To reduce the height of the semiconductor device 1, it is desirable that the height H3 be equal to or smaller than, for example, ½ of the height H1. Since half etching to be described layer is performed in manufacturing, the height H3 is, for example, about half the height H1.

A height H4 from the lower surface of the lead frame 20 to the upper surface of the notch portion NP of the projecting portion 22 of the lead frame 20 and a height H5 from the lower surface of the lead frame 30 to the upper surface of the notch portion NP of the projecting portion 32 of the lead frame 30 are designed in consideration of, for example, the visibility of a fillet, which will be described later, at the time when the semiconductor device 1 is implemented on the main substrate using the fillet. The height H5 is substantially equal to the height H4. The heights H4 and H5 are, for example, equal to or greater than 100 μm.

A length L1 of the projecting portion 22 of the lead frame 20 in the X direction is designed in consideration of the possibility that the package member 50 will be chipped due to dicing in manufacturing, for example. A length L2 of the projecting portion 32 of the lead frame 30 in the X direction is designed in a similar manner to the length L1. The lengths L1 and L2 are, for example, equal to or greater than 50 μm.

In the base portion 21 of the lead frame 20, its length L3 in the X direction from a position in contact with the projecting portion 22 to the stepped portion 25 is designed to be, for example, equal to or greater than half the thickness of half etching or equal to or greater than ⅓ thereof.

A length L4 of the bottom surface 25a of the stepped portion 25 of the lead frame 20 in the X direction is designed in consideration of, for example, the size of the first surface S1 of the lead frame 20. The length L4 is, for example, equal to or greater than 30 μm.

The semiconductor element 10 is provided on the bottom surface 25a of the stepped portion 25 of the lead frame 20 with the predetermined positional accuracy. In a case where the lower surface of the semiconductor element 10 mounted on the bottom surface 25a (i.e., in contact with the bottom surface 25a) is relatively small in area, there is a possibility that coupling between the semiconductor element 10 and the lead frame 20 will not be sufficient. Thus, it is preferable that the area of the portion in which the element portion 11 of the semiconductor element 10 is in contact with the bottom surface 25a of the stepped portion 25 of the lead frame 20 be equal to or greater than ½ of the area of the lower surface of the element portion 11.

### 1.2 Implementation Example of Semiconductor Device

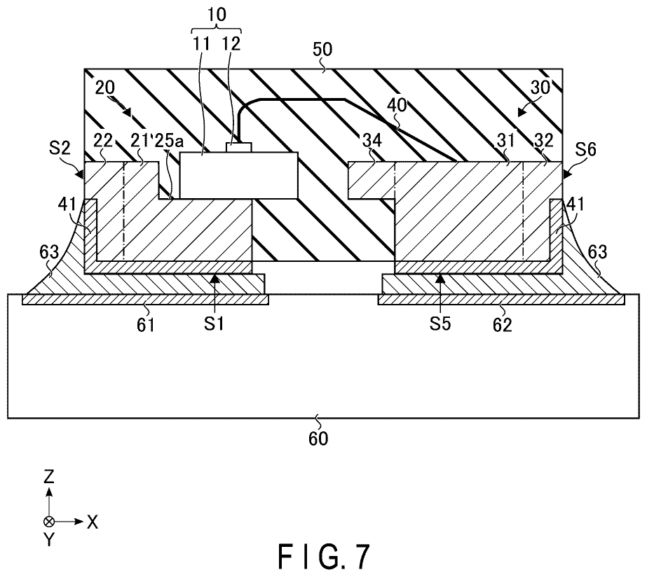

Next, an implementation example of the semiconductor device 1 will be described. FIG. 7 is a cross-sectional view showing a structure of an implementation example of the semiconductor device 1. FIG. 7 shows a structure in which the semiconductor device 1 is mounted on a main substrate 60.

As shown in FIG. 7, the lead frame 20 is provided on a pad (for example, an interconnect or a terminal) 61 of the main substrate 60 via a conductive member 63. The conductive member 63 is provided between the first surface S1 of the lead frame 20 and the pad 61. Since the lead frame 20 has a WF structure, the conductive member 63 is provided on the second surface S2 of the lead frame 20, too. The conductive member 63 is also referred to as a “fillet”. The fillet 63 is in contact with the first surface S1 of the lead frame 20 and the pad 61, and provides electrical coupling between the first surface S1 of the lead frame 20 and the pad 61. The conductive member (or fillet) 63 includes, for example, solder. The pad 61 is provided on the implementation surface of the main substrate 60. The pad 61 includes, for example, copper or aluminum.

The lead frame 30 is provided on the pad (for example, an interconnect or a terminal) 62 of the main substrate 60 via the conductive member 63. The conductive member 63 is provided between the fifth surface S5 of the lead frame 30 and the pad 62. Since the lead frame 30 has a WF structure, the conductive member 63 is provided on the sixth surface S6 of the lead frame 30, too. The fillet 63 is in contact with the fifth surface S5 of the lead frame 30 and the pad 62, and provides electrical coupling between the fifth surface S5 of the lead frame 30 and the pad 62. The pad 62 is provided on the implementation surface of the main substrate 60. The pad 62 includes, for example, copper or aluminum.

### 1.3 Manufacturing Method of Semiconductor Device

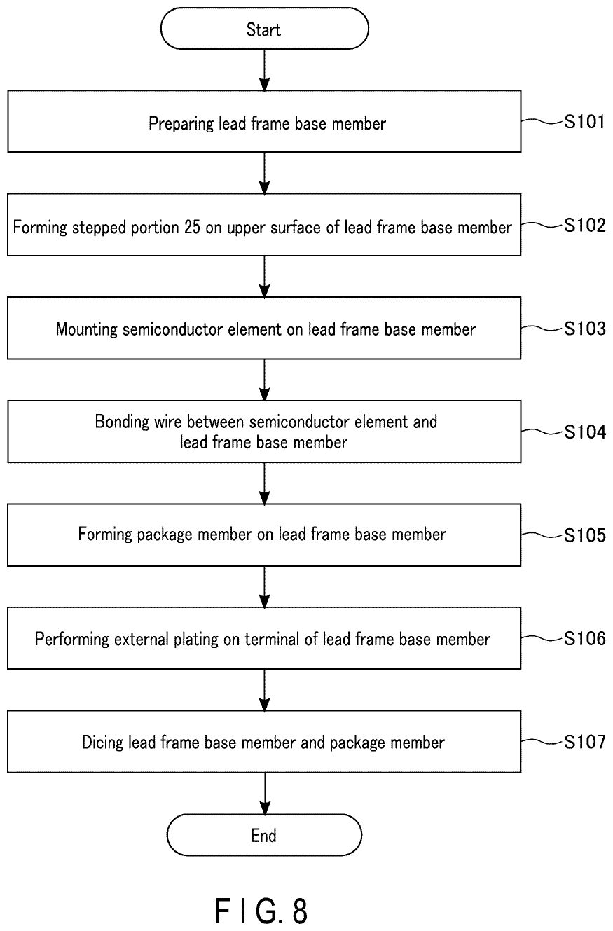

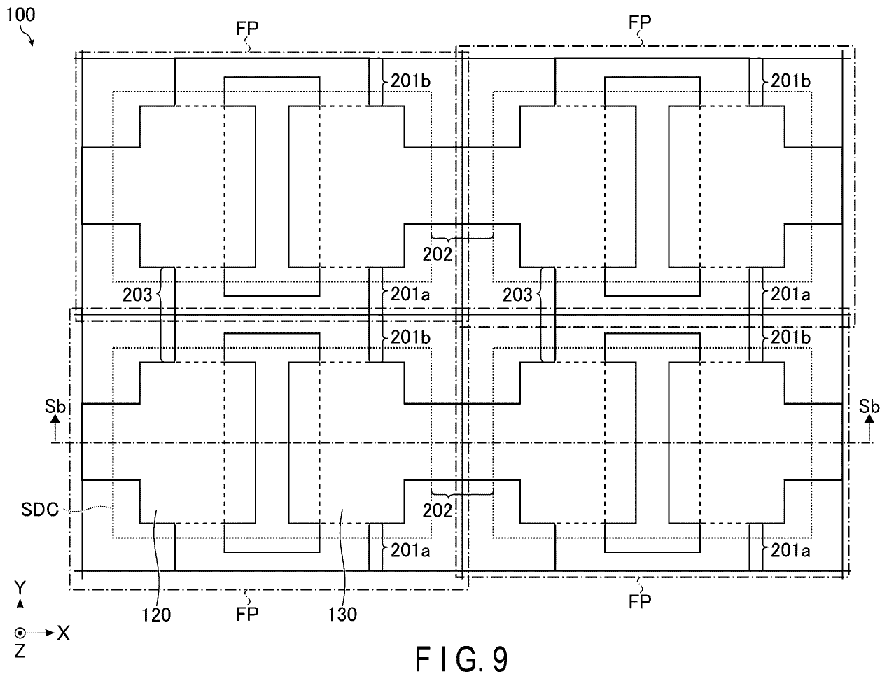

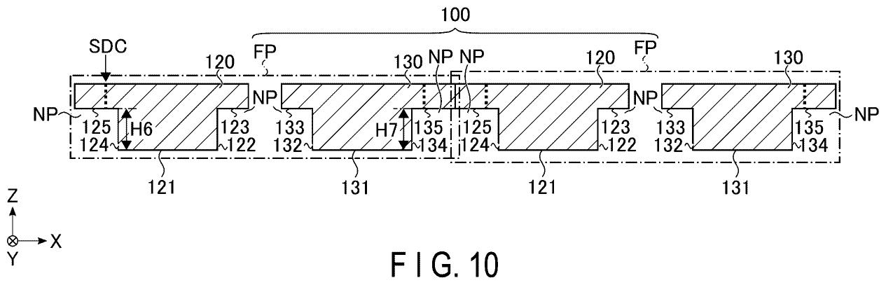

Next, the manufacturing method of the semiconductor device 1 will be described with reference to FIG. 8 to FIG. 15. FIG. 8 is a flowchart showing an example of the method of manufacturing the semiconductor device 1. FIG. 8 shows main steps in the method of manufacturing the semiconductor device 1. FIG. 9 to FIG. 15 show steps in the method of manufacturing the semiconductor device 1. FIG. 9 shows a planar view of the lead frame base member as viewed from the upper surface side. FIG. 10 to FIG. 15 are each a cross-sectional view taken along line Sb-Sb in FIG. 9.

First, as shown in FIG. 9, a lead frame base member (lead frame base) 100 is prepared (S101). The lead frame base member 100 is formed using, for example, a mold. The lead frame base member 100 includes a part (hereinafter referred to as a “frame portion FP”) corresponding to the semiconductor device 1 including the lead frames 20 and 30. The lead frame base member 100 includes a plurality of frame portions FP. In the lead frame base member 100, the plurality of frame portions FP are arranged side by side in the X direction and the Y direction.

The lead frame base member 100 (frame portion FP) includes a base member (base) 120 corresponding to the lead frame 20 (hereinafter also simply referred to as a “base member 120” or a “first base 120”) and a base member (base) 130 corresponding to the lead frame 30 (hereinafter also simply referred to as a “base member 130” or a “second base 130”). In the frame portion FP, the base member 120 is arranged so as to face the base member 130 in the X direction. The base member 120 and the base member 130 are connected together by connecting portions 201a and 201b. The connecting portions 201a and 201b correspond to suspension pins.

The frame portion FP on the left side in the drawing sheet and the frame portion FP on the right side in the drawing sheet, which are adjacent to each other in the X direction, are connected together by a connecting portion 202. The connecting portion 202 is an outer lead.

The frame portion FP on the upper side in the drawing sheet and the fame portion FP on the lower side in the drawing sheet, which are adjacent to each other in the Y direction, are connected together by a connecting portion 203. The connecting portion 203 includes the connecting portion 201a of the frame portion FP on the upper side in the drawing sheet and the connecting portion 201b of the frame portion FP on the lower side in the drawing sheet.

In the frame portion FP, a broken line shown in a rectangular shape outside the base members 120 and 130 represents a dicing cut surface SDC.

As shown in FIG. 10, in the frame portion FP, the base member 120 has notch portions NP at both ends on the lower surface (hereinafter referred to as a “surface 121”). In the base member 120, the notch portion NP closer to the base member 130 includes a side surface (hereinafter referred to as a “surface 122”) in contact with the right end of the surface 121 and a lower surface (hereinafter referred to as a “surface 123”) in contact with the upper end of the surface 122. In the base member 120, the notch portion NP far from the base member 130 includes a side surface (hereinafter referred to as a “surface 124”) in contact with the left end of the surface 121 and a lower surface (hereinafter referred to as a “surface 125”) in contact with the upper end of the surface 124.

In the frame portion FP, the base member 130 has notch portions NP at both ends on the lower surface (hereinafter referred to as a “surface 131”). In the base member 130, the notch portion NP closer to the base member 120 includes a side surface (hereinafter referred to as a “surface 132”) in contact with the left end of the surface 131 and a lower surface (hereinafter referred to as a “surface 133”) in contact with the upper end of the surface 132. In the base member 130, the notch portion NP far from the base member 120 includes a side surface (hereinafter referred to as a “surface 134”) in contact with the right end of the surface 131 and a lower surface (hereinafter referred to as a “surface 135”) in contact with the upper end of the surface 134. In two frame portions FP adjacent to each other in the X direction, the surface 135 of the frame portion FP on the left side in the drawing sheet is flush with the surface 125 of the frame portion FP on the right side in the drawing sheet.

The lead frame base member 100 includes, for example, copper (or aluminum). The lead frame base member 100 has a thickness of, for example, 150μm or greater and 200μm or smaller. A height H6 from the surface 121 to the upper surface of the notch portion NP and a height H7 from the surface 131 to the upper surface of the notch portion NP is smaller than the height from the lower surface to the upper surface of the lead frame base member 100 (the thickness of the lead frame base member 100). The height H7 is substantially equal to the height H6. The heights H6 and H7 are, for example, equal to or greater than 100 μm.

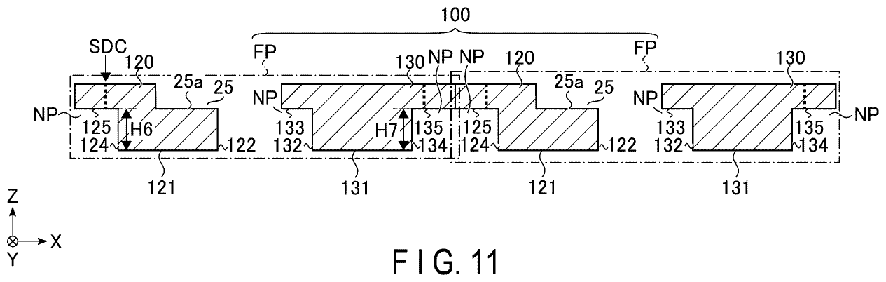

Next, as shown in FIG. 11, the stepped portion 25 is formed on the upper surface of the lead frame base member 100 (S102). More specifically, the stepped portion 25 is formed on an end portion of the upper surface of the base member 120 of the lead frame base member 100, in which the end portion is closer to the base member 130. Specifically, for example, the end portion of the upper surface of the base member 120 of the lead frame base member 100, in which the end portion is closer to the base member 130, is half-etched. At this time, etching is performed such that the base member 120 remains at both sides in the Y direction of the stepped portion 25. This forms the stepped portion 25 that has the side wall 25b in the X direction and the mutually facing side walls 25c and 25d in the Y direction.

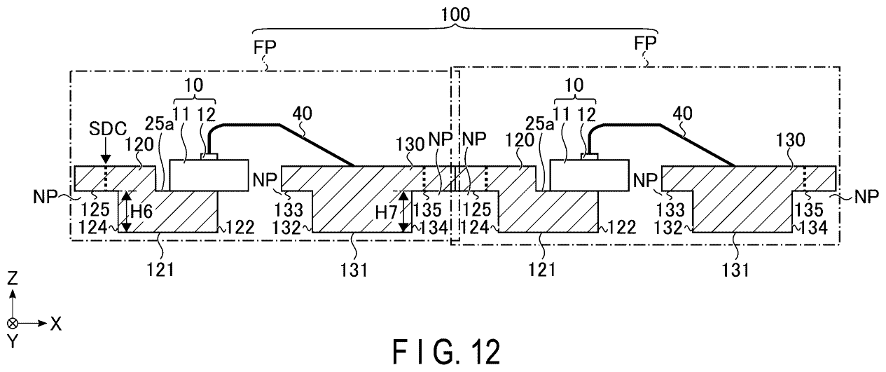

Next, as shown in FIG. 12, the semiconductor element 10 is mounted on the lead frame base member 100 (S103). Specifically, for example, the semiconductor element 10 is formed on the bottom surface 25a of the stepped portion 25 of the base member 120 of the lead frame base member 100 while a conductive member (not shown) intervenes between the bottom surface 25a and the semiconductor element 10. A wire is bonded between the semiconductor element 10 and the lead frame base member 100 (S104). Specifically, the bonding wire 40 is bonded between the pad 12 of the semiconductor element 10 and the base member 130 of the lead frame base member 100. By this, the pad 12 of the semiconductor element 10 and the base member 130 are electrically coupled to each other via the bonding wire 40.

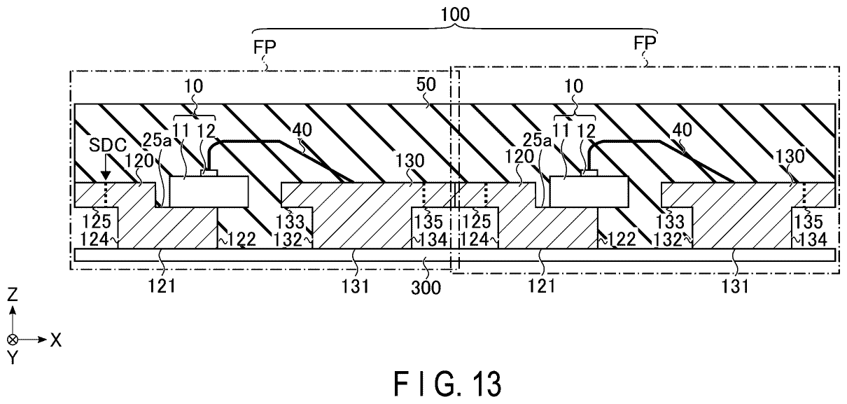

Next, as shown in FIG. 13, the package member 50 is formed on the lead frame base member 100 (S105). Specifically, for example, first, a rear tape 300 is pasted on the lower surface of the lead frame base member 100. The rear tape 300 is formed to prevent a resin from being leaked to the surface 121 and the surface 131 of the lead frame base member 100 in formation of the package member 50. Next, the package member 50 is formed on the upper surface of the lead frame base member 100 in which the semiconductor element 10 and the bonding wire 40 are formed, and is formed in a space surrounded by the semiconductor element 10 and the base members 120 and 130. The package member 50 is formed using, for example, a mold. The package member 50 is injected from an inlet of the mold, so that a space between the lead frame base member 100 and the mold is filled with the package member 50. By this, the package member 50 is formed on the upper surface of the lead frame base member 100 and in the space surrounded by the semiconductor element 10 and the base members 120 and 130. That is, part of each of the base members 120 and 130 of the lead frame base member 100 is covered with the package member 50. The semiconductor element 10 and the bonding wire 40 on the lead frame base member 100 are sealed with the package member 50. After the package member 50 is formed, the rear tape 300 is removed.

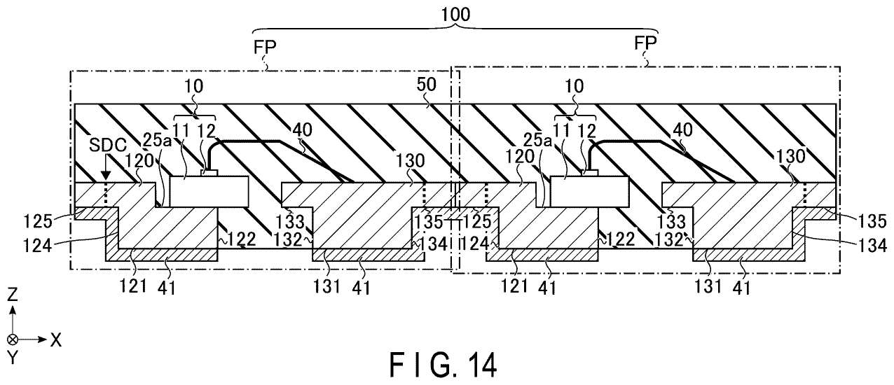

Next, as shown in FIG. 14, external plating is performed on a terminal of the lead frame base member 100 (S106). Specifically, the plating layer 41 is formed using an electrolytic plating method on the lower surfaces and the side surface (surfaces 121, 124, and 125) exposed from the package member 50 of the base member 120 of the lead frame base member 100 and on the lower surfaces and the side surface (surfaces 131, 134, and 135) exposed from the package member 50 of the base member 130 of the lead frame base member 100. The plating layer 41 includes, for example, tin or solder.

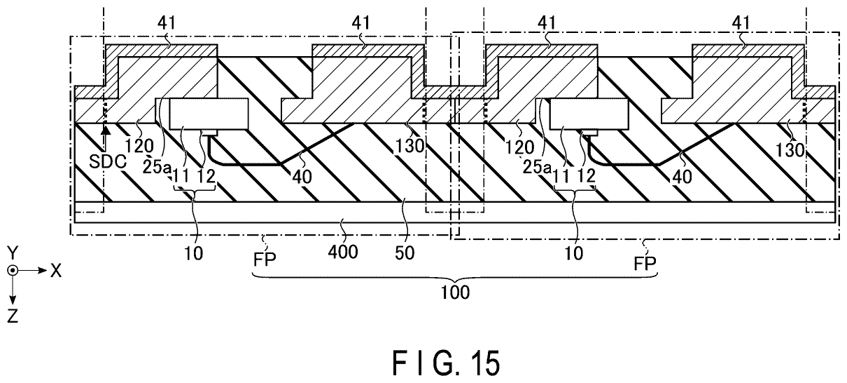

Next, as shown in FIG. 15, dicing is performed on the lead frame base member 100 and the package member 50 (S107). Specifically, for example, first, a dicing tape 400 is pasted on the upper surface of the package member 50. The dicing tape 400 is formed to retain a plurality of divided individual semiconductor devices 1 at the time when the lead frame base member 100 is divided into the plurality of individual semiconductor devices 1 through dicing. Next, the lead frame base member 100 and the package member 50 are diced on a dicing cut surface SDC from the lower surface side of the lead frame base member 100 using a dicing blade. After dicing, the dicing tape 400 is removed. By this, the lead frame base member 100 is divided into the plurality of individual semiconductor devices 1, so that such a semiconductor device 1 as shown in FIG. 6 can be obtained. The steps of manufacturing the semiconductor device 1 are thus completed.

Hereinafter, the semiconductor device 1 is implemented on the main substrate 60 through a reflow step as shown in FIG. 7. The fillet 63 is formed on the side surface of the semiconductor device 1. The fillet 63 fixes the semiconductor device 1 on the main substrate 60, provides electric coupling between the first surface S1 of the lead frame 20 and the pad 61 of the main substrate 60, and provides electric coupling between the fifth surface S5 of the lead frame 30 and the pad 62 of the main substrate 60.

Thereafter, various inspections such as automated optical inspection (AOI) are executed on the semiconductor device 1 on the main substrate 60 by a test device. For example, shapes of the fillets 63 formed on the lead frames 20 and 30 are each inspected through the AOI. By this, a quality of a coupling state between the semiconductor device 1 and the main substrate 60 is determined.

After various inspections, the main substrate 60 on which the semiconductor device 1 according to the present embodiment is implemented or equipment including the semiconductor device 1 according to the present embodiment is shipped to market or a user.

In the structure in which the semiconductor device having the WF structure is implemented on the main substrate, generally, the visibility of a fillet (side fillet) becomes more dominant as the WF length increases.

Therefore, one option is to increase the WF length, that is, the thickness of the lead frame. However, a semiconductor package reduced in height has a restriction on the gap between the thickness of the package and the overall height including the thickness of the lead frame, the thickness of the semiconductor element, and looping of a wire. This makes it difficult to increase the thickness of the lead frame more than necessary. As described above, in the process of manufacturing the semiconductor device having the WF structure, the reduction in height of the semiconductor device and the increase in film thickness of the lead frame are in a trade-off relationship. With the structure in which the semiconductor device having an equal WF length and lead frame thickness is implemented on the main substrate, there is a possibility that the visibility of the fillet will decrease.

In the semiconductor device 1 according to the present embodiment, the stepped portion 25 is provided on the end portion of the upper surface of the lead frame 20, in which the end portion is closer to the lead frame 30. The semiconductor element 10 is provided on the bottom surface 25a of the stepped portion 25. This enables the present embodiment to maximize the WF length (height of a side surface electrode), that is, the height H1 of the second surface S2 of the lead frame 20, and the height H2 of the sixth surface S6 of the lead frame 30 without increasing the thickness of the semiconductor device 1. Thus, the height H4 from the lower surface of the lead frame 20 to the upper surface of the notch portion NP of the projecting portion 22 of the lead frame 20 and the height H5 from the lower surface of the lead frame 30 to the upper surface of the notch portion NP of the projecting portion 32 of the lead frame 30 can be set to be relatively great, so that the height of the plating layer 41 can be set to be great. In this manner, in implementation of the semiconductor device 1 on the main substrate 60, the fillet 63 is formed up to the height of the plating layer 41. This realizes improvement in the visibility of the fillet 63. That is, inspections of the implementation state of the semiconductor device 1 through AOI can be easily performed. By this, the semiconductor device 1 of the present embodiment can be improved in the accuracy of inspections of the implementation state. This realizes improvement in reliability of a quality of the main substrate 60 or equipment including the semiconductor device 1 according to the present embodiment.

Furthermore, at the time when the lead frame base member and the package member are cut by dicing, due to stress, peeling may occur from the outer periphery, between a base member corresponding to the lead frame and the package member.

In the semiconductor device 1 according to the present embodiment, the stepped portion 25 has the side wall 25b in the X direction and has the mutually facing side walls 25c and 25d in the Y direction. Three side surfaces of the semiconductor element 10 are surrounded by the side walls 25b, 25c, and 25d of the stepped portion 25. By this, the progress of peeling between the base member 120 and the package member 50, which starts from the outer periphery due to stress occurring at the time of a dicing cut, stops at the stepped portion 25. Therefore, the progress of peeling between the base member 120 and the package member 50 can be prevented. In this manner, the semiconductor device 1 can be prevented from deteriorating in moisture resistance and can be improved in reliability.

As described above, the semiconductor device 1 and its manufacturing method according to the present embodiment can maximize the WF length of the semiconductor device 1 (the height of the side surface electrode) and can improve reliability in implementation of the semiconductor device 1 on the main substrate 60. Furthermore, the semiconductor device 1 can be improved in reliability.

### 2. Second Embodiment

A semiconductor device according to a second embodiment will be described. A semiconductor device 1A according to a second embodiment differs from that of the first embodiment in terms of structure of the lead frame 20 and method of manufacturing the semiconductor device 1A. The following description will concentrate on the features different from the first embodiment.

### 2.1 Structure of Semiconductor Device

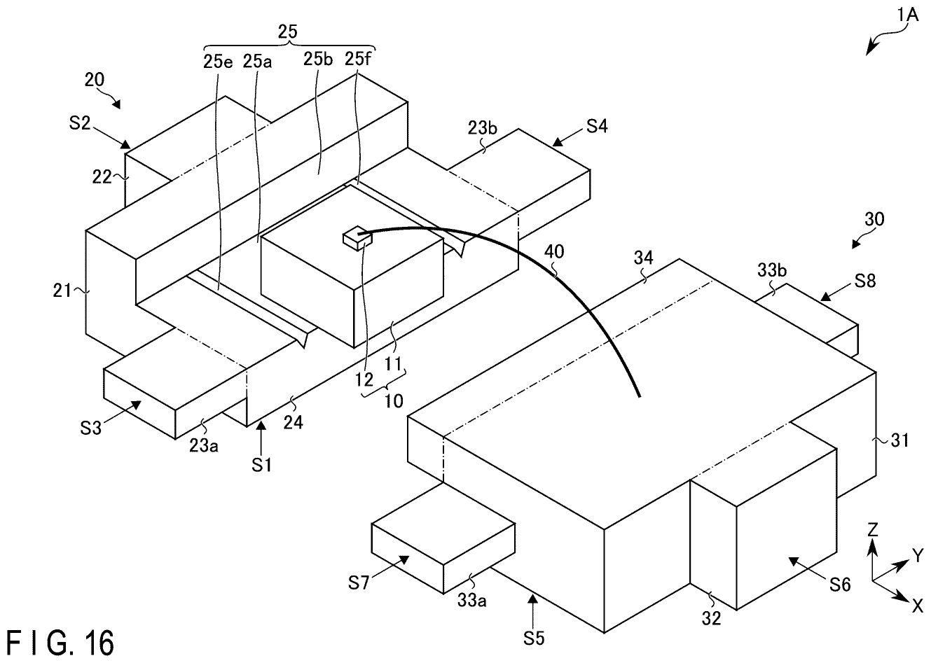

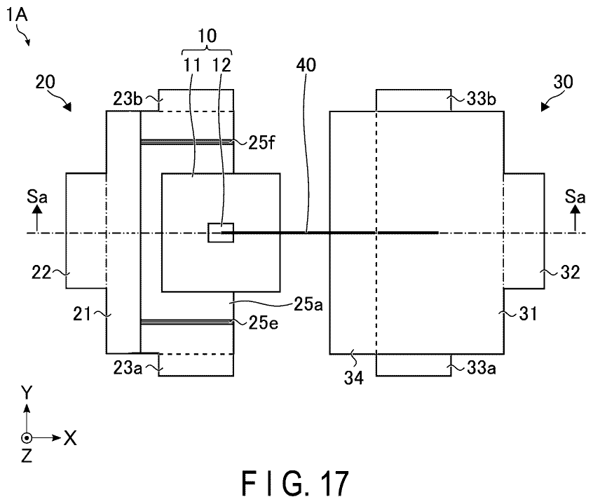

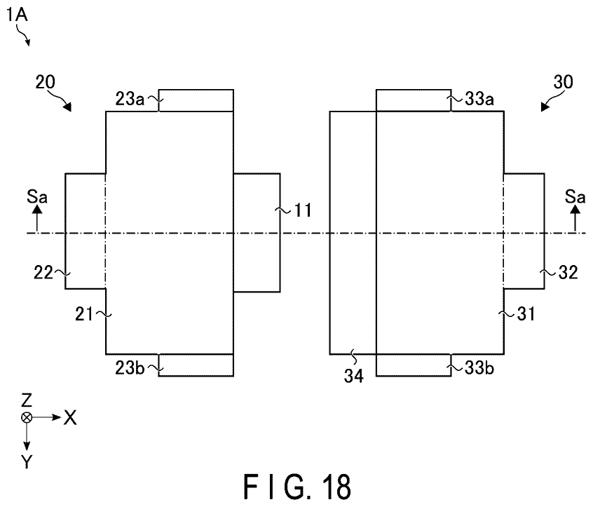

A structure of the semiconductor device 1A will be described with reference to FIG. 16 to FIG. 18. FIG. 16 is a perspective view showing an example of a structure of the semiconductor device 1A. FIG. 16 shows a structure of the semiconductor device 1A as viewed from the upper surface side with the package member 50 being transparent, as in FIG. 3 described in the first embodiment. FIG. 17 and FIG. 18 each show a planar view showing an example of the structure of the semiconductor device 1A. FIG. 17 shows a structure of the semiconductor device 1A as viewed from the upper surface side with the package member 50 being transparent, as in FIG. 4 described in the first embodiment. FIG. 18 shows a structure of the semiconductor device 1A as viewed from the lower surface side with the package member 50 being transparent, as in FIG. 5 described in the first embodiment.

As shown in FIG. 16 to FIG. 18, the semiconductor device 1A includes the semiconductor element 10, the lead frames 20 and 30, and the bonding wire 40.

The stepped portion 25 of the lead frame 20 includes the bottom surface 25a and the side wall 25b. The stepped portion 25 has the side wall 25b in the X direction. The bottom surface 25a of the stepped portion 25 has grooves 25e and 25f. The grooves 25e and 25f are each formed into a letter V shape as viewed in the X direction. The grooves 25e and 25f each extend from the side wall 25b to the end portion closer to the lead frame 30, of the bottom surface 25a, in the X direction. The grooves 25e and 25f are spaced apart from each other in the Y direction. The semiconductor element 10 is formed between the grooves 25e and 25f. The semiconductor element 10 faces the side wall 25b in the X direction.

The base portion 21 of the lead frame 20 is formed into a substantially letter L shape as viewed in the Y direction. The upper surface of each of the projecting portions 23a and 23b of the lead frame 20 is flush with the bottom surface 25a of the stepped portion 25. The projecting portions 24a and 24b are eliminated from the lead frame 20.

A position of the upper surface of each of the projecting portions 33a and 33b of the lead frame 30 is the same as that of the upper surface of each of the projecting portions 23a and 23b of the lead frame 20.

Three-dimensional structures and planar structures of the semiconductor device 1A other than those described above are similar to those shown in FIG. 3 to FIG. 5 described in the first embodiment.

A cross-sectional structure of the semiconductor device 1A taken along the line Sa-Sa in FIG. 17 and FIG. 18 is similar to that of FIG. 6 described in the first embodiment.

### 2.2 Manufacturing Method of Semiconductor Device

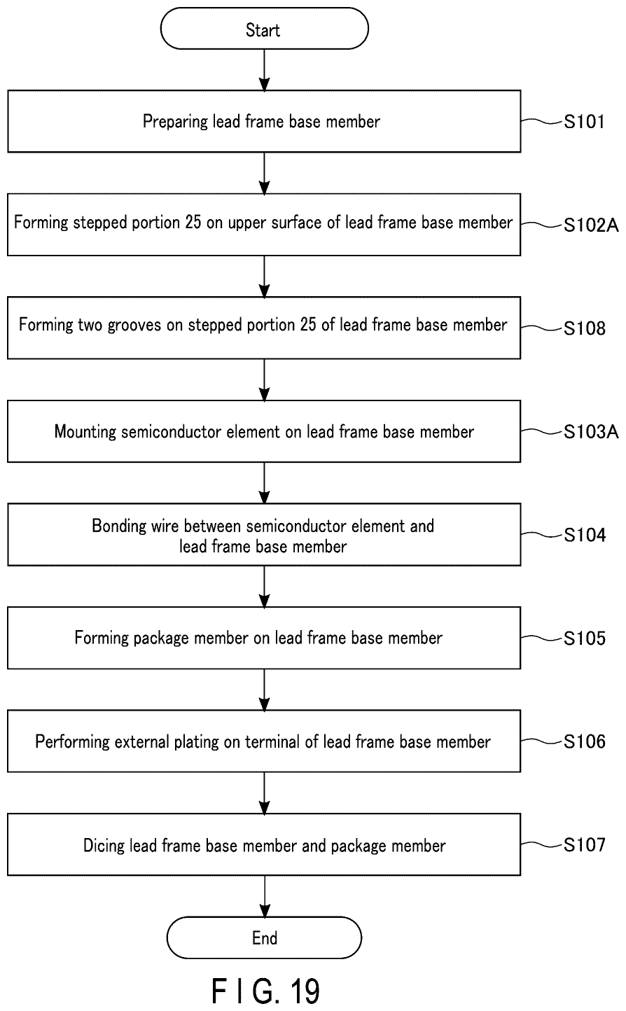

The method of manufacturing the semiconductor device 1A will be described with reference to FIG. 19. FIG. 19 is a flowchart showing an example of the method of manufacturing the semiconductor device 1A. FIG. 19 shows main steps in the method of manufacturing the semiconductor device 1A.

In the flowchart shown in FIG. 19, S102 of the flowchart in FIG. 8 described in the first embodiment is replaced with S102A, S103 is replaced with S103A, and S108 is added between S102A and S103A. The steps other than S102A, S103A, and S108 are the same as those of the flowchart in FIG. 8 described in the first embodiment.

After S101 is performed as in the first embodiment, the stepped portion 25 is formed on the upper surface of the lead frame base member 100 in S102A. More specifically, the stepped portion 25 is formed on an end portion of the upper surface of the base member 120 of the lead frame base member 100 in which the end portion is closer to the base member 130. Specifically, for example, the end portion of the upper surface of the base member 120 of the lead frame base member 100, in which the end portion is closer to the base member 130, is half-etched. At this time, etching is performed such that the base member 120 does not remain at both sides in the Y direction of the stepped portion 25. This forms the stepped portion 25 that has the side wall 25b in the X Direction.

After the stepped portion 25 is formed, two grooves are formed on the stepped portion 25 of the lead frame base member 100 (S108). More specifically, grooves 25e and 25f are formed on the bottom surface 25a of the stepped portion 25 of the lead frame base member 100. Specifically, for example, coining is performed on the bottom surface 25a of the stepped portion 25 of the lead frame base member 100. This forms the grooves 25e and 25f which are spaced apart from each other in the Y direction and which each extend from the side wall 25b in the X direction to the end portion of the bottom surface 25a in which the end portion is closer to the lead frame 30.

After the grooves 25e and 25f are formed, in S103A, the semiconductor element 10 is mounted on the lead frame base member 100. Specifically, for example, the semiconductor element 10 is formed between the grooves 25e and 25f of the bottom surface 25a of the stepped portion 25 of the base member 120 of the lead frame base member 100 while a conductive member (not shown) intervenes between the semiconductor element 10 and the grooves 25e and 25f.

Thereafter, S104 to S107 are performed in the same manner as the first embodiment.

As with the first embodiment, according to the semiconductor device 1A and its manufacturing method according to the present embodiment, the WF length of the semiconductor device 1A (the height of the side surface electrode) can be maximized and reliability in implementation of the semiconductor device 1A on the main substrate 60 can be improved.

In the semiconductor device 1A according to the present embodiment, the stepped portion 25 has the side wall 25b in the X direction. The bottom surface 25a of the stepped portion 25 has grooves 25e and 25f. The grooves 25e and 25f each extend from the side wall 25b to the end portion closer to the lead frame 30, of the bottom surface 25a, in the X direction. The grooves 25e and 25f are spaced apart from each other in the Y direction. The semiconductor element 10 is formed between the grooves 25e and 25f. The semiconductor element 10 faces the side wall 25b in the X direction. By this, the progress of peeling between the base member 120 and the package member 50, which starts from the outer periphery due to stress occurring at the time of a dicing cut, stops at the grooves 25e and 25f. Therefore, the progress of peeling between the base member 120 and the package member 50 can be prevented. In this manner, the semiconductor device 1A can be prevented from deteriorating in moisture resistance and can be improved in reliability. As discussed above, according to the semiconductor device 1A and its manufacturing method according to the present embodiment, reliability of the semiconductor device 1A can be improved.

### 3. Third Embodiment

A semiconductor device according to a third embodiment will be described. A semiconductor device 1B according to the third embodiment differs from that of the first embodiment in that it includes a semiconductor element (semiconductor chip) 70. Furthermore, the semiconductor device 1B according to the third embodiment differs from that of the first embodiment in terms of a structure of the lead frame 30 and a method of manufacturing the semiconductor device 1B. The following description will concentrate on the features different form the first embodiment.

### 3.1 Structure of Semiconductor Device

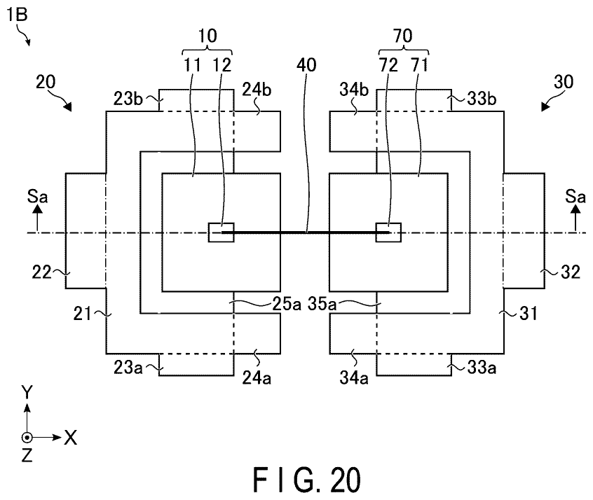

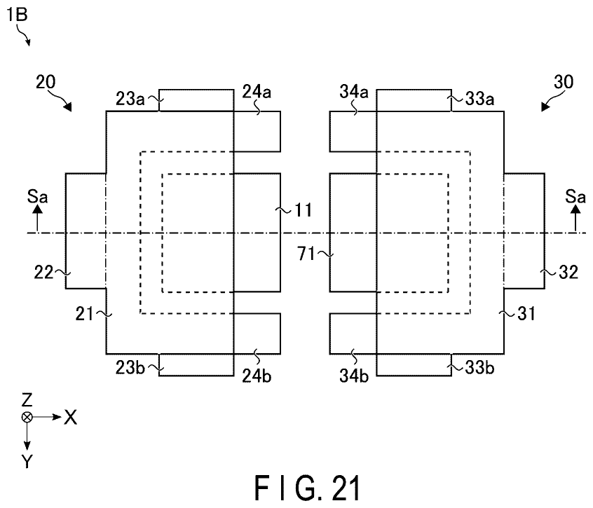

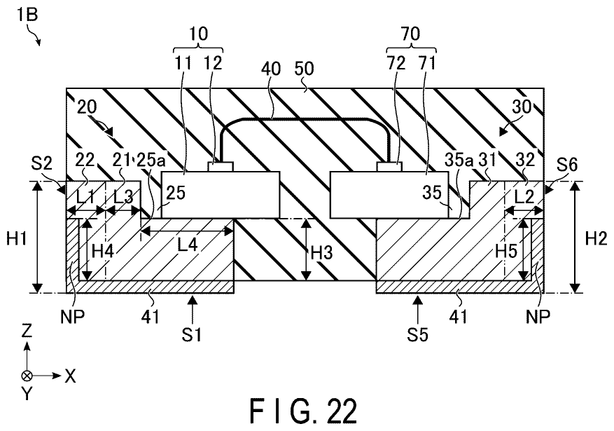

A structure of the semiconductor device 1B will be described with reference to FIG. 20 to FIG. 22. FIG. 20 and FIG. 21 each show a planar view showing an example of the structure of the semiconductor device 1B. FIG. 20 shows a structure of the semiconductor device 1B as viewed from the upper surface side with the package member 50 being transparent, as in FIG. 4 described in the first embodiment. FIG. 21 shows a structure of the semiconductor device 1B as viewed from the lower surface side with the package member 50 being transparent, as in FIG. 5 described in the first embodiment. FIG. 22 is a cross-sectional view showing an example of a structure of the semiconductor device 1B. FIG. 22 shows a cross-sectional structure of the semiconductor device 1B taken along the line Sa-Sa in FIG. 20 and FIG. 21.

As shown in FIG. 20 to FIG. 22, the semiconductor device 1B includes the semiconductor elements 10 and 70, the lead frames 20 and 30, the bonding wire 40, and the package member 50.

The semiconductor element 70 has a structure similar to that of the semiconductor element 10. The semiconductor element 70 includes an element portion 71 and a pad (or a node, a terminal) 72. The element portion 71 corresponds to an element portion 11. The pad 72 corresponds to the pad 12.

The lead frame 30 has a structure similar to that of the lead frame 20. The lead frame 30 includes the base portion 31 and the projecting portions 32, 33a, 33b, 34a, and 34b. The base portion 31 corresponds to the base portion 21. The projecting portions 32, 33a, 33b, 34a, and 34b respectively correspond to the projecting portions 22, 23a, 23b, 24a, and 24b. The base portion 31 has a stepped portion 35. The stepped portion 35 corresponds to the stepped portion 25. The lead frame 30 has the stepped portion 35 on the end portion of the upper surface, in which the end portion is closer to the lead frame 20. The stepped portion 35 has a bottom surface 35a and side walls 35b, 35c, and 35d. Illustration of the side walls 35b, 35c, and 35d is omitted. The bottom surface 35a and the side walls 35b, 35c, and 35d respectively correspond to the bottom surface 25a and the side walls 25b, 25c, and 25d.

The semiconductor element 70 is provided on the bottom surface 35a of the stepped portion 35.

The other end of the bonding wire 40 is coupled to the upper surface of the pad 72. The bonding wire 40 electrically couples the pad 12 of the semiconductor element 10 and the base portion 31 of the lead frame 30 via the pad 72 of the semiconductor element 70.

Planar structures and cross-sectional structures of the semiconductor device 1B other than those described above are similar to those shown in FIG. 4 to FIG. 6 described in the first embodiment.

### 3.2 Manufacturing Method of Semiconductor Device

A method of manufacturing the semiconductor device 1B will be described.

In the method of manufacturing the semiconductor device 1B, in step S102 of the flowchart in FIG. 8 described in the first embodiment, in the same manner as the base member 120, the stepped portion 35 is formed on the end portion of the upper surface of the base member 130, in which the end portion is closer to the base member 120. In step S103 of the flowchart in FIG. 8, the semiconductor element 70 is formed on the bottom surface 35a of the stepped portion 35 of the base member 130, in the same manner as the base member 120. In step S104 of the flowchart in FIG. 8, the bonding wire 40 is bonded between the pad 12 of the semiconductor element 10 and the pad 72 of the semiconductor element 70.

The steps other than the above are similar to those of the first embodiment.

The present embodiment produces advantageous effects similar to those of the first embodiment.

### 4. Fourth Embodiment

A semiconductor device according to a fourth embodiment will be described. A semiconductor device 1C according to the fourth embodiment differs from that of the second embodiment in that it includes a semiconductor element 70. Furthermore, the semiconductor device 1C according to the fourth embodiment differs from that of the second embodiment in terms of a structure of the lead frame 30 and a method of manufacturing the semiconductor device 1C. The following description will concentrate on the feature different form the second embodiment.

### 4.1 Structure of Semiconductor Device

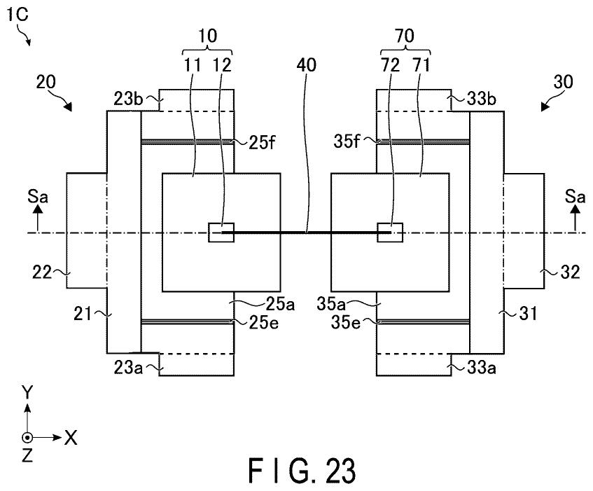

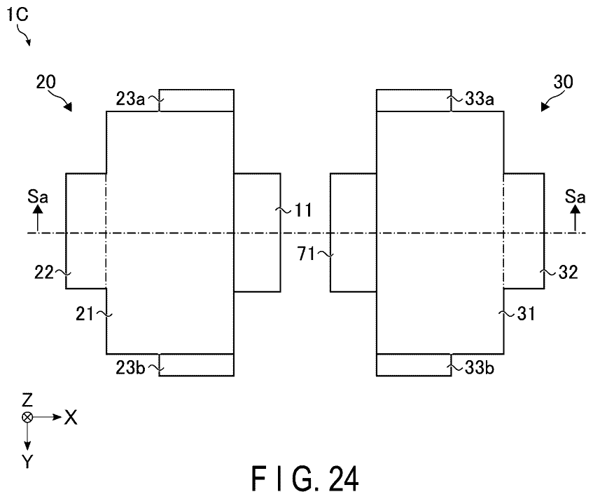

A structure of the semiconductor device 1C will be described with reference to FIG. 23 and FIG. 24. FIG. 23 and FIG. 24 each show a planar view showing an example of the structure of the semiconductor device 1C. FIG. 23 shows a structure of the semiconductor device 1C as viewed from the upper surface side with the package member 50 being transparent, as in FIG. 4 described in the first embodiment. FIG. 24 shows a structure of the semiconductor device 1C as viewed from the lower surface side with the package member 50 being transparent, as in FIG. 5 described in the first embodiment.

As shown in FIG. 23 and FIG. 24, the semiconductor device 1B includes the semiconductor element 10 and 70, the lead frames 20 and 30, and the bonding wire 40.

The semiconductor element 70 has a structure similar to that of the semiconductor element 10. The semiconductor element 70 includes an element portion 71 and a pad (or a node, a terminal) 72. The element portion 71 corresponds to an element portion 11. The pad 72 corresponds to the pad 12.

The lead frame 30 has a structure similar to that of the lead frame 20. The lead frame 30 includes the base portion 31 and projecting portions 32, 33a, and 33b. The base portion 31 corresponds to the base portion 21. The projecting portions 32, 33a 33b respectively correspond to the projecting portions 22, 23a, and 23b. The base portion 31 has a stepped portion 35. The stepped portion 35 corresponds to the stepped portion 25. The lead frame 30 has the stepped portion 35 on the end portion of the upper surface, in which the end portion is closer to the lead frame 20. The stepped portion 35 has the bottom surface 35a and the side wall 35b. An illustration of the side wall 35b is omitted. The bottom surfaces 35a and the side wall 35b respectively correspond to the bottom surface 25a and the side wall 25b. The bottom surface 35a has the grooves 35e and 35f. The grooves 35e and 35f respectively correspond to the grooves 25e and 25f.

The semiconductor element 70 is provided between the grooves 35e and 35f of the bottom surface 35a of the stepped portion 35.

The other end of the bonding wire 40 is coupled to the upper surface of the pad 72. The bonding wire 40 electrically couples the pad 12 of the semiconductor element 10 and the base portion 31 of the lead frame 30 via the pad 72 of the semiconductor element 70.

Planar structures of the semiconductor device 1C other than those described above are similar to those shown in FIG. 17 and FIG. 18 described in the second embodiment.

A cross-sectional structure of the semiconductor device 1C taken along the line Sa-Sa in FIG. 23 and FIG. 24 is similar to that of FIG. 22 described in the third embodiment.

### 4.2 Manufacturing Method of Semiconductor Device

A method of manufacturing the semiconductor device 1C will be described.

The method of manufacturing the semiconductor device 1C forms the stepped portion 35 on the end portion of the upper surface of the base member 130, in which the end portion is closer to the base member 120 in step S102A of the flowchart in FIG. 19 described in the second embodiment, in the same manner as the base member 120. In step S108 of the flowchart in FIG. 19, the grooves 35e and 35f are formed on the bottom surface 35a of the stepped portion 35 of the base member 130, in the same manner as the base member 120. In step S103A of the flowchart in FIG. 19, the semiconductor element 70 is formed between the grooves 35e and 35f of the bottom surface 35a of the stepped portion 35 of the base member 130, in the same manner as the base member 120. In step S104 of the flowchart in FIG. 19, the bonding wire 40 is bonded between the pad 12 of the semiconductor element 10 and the pad 72 of the semiconductor element 70.

The steps other than the above are similar to those of the first embodiment.

The present embodiment produces advantageous effects similar to those of the second embodiment.

### 5. Modifications, Etc.

As described above, a semiconductor device (1) according to an embodiment includes a first frame (30), a second frame (20), a first semiconductor chip (10), a wire (40), and a resin (50). The second frame (20) is arranged so as to face the first frame (30) in a first direction (X), and has a stepped portion (25) on an end portion of an upper surface, the end portion being closer to the first frame. The first semiconductor chip (10) is arranged on a bottom surface (25a) of the stepped portion (25) of the second frame (20). The wire (40) provides electrical coupling between the first semiconductor chip (10) and the first frame (30). The resin (50) covers part of each of the first frame (30) and the second frame (20) and seals the first semiconductor chip (10) and the wire (40). A lower surface (S5) of the first frame (30) and a first side surface (S6) of the first frame, the first side surface being far from the second frame (20) in the first direction (X), are exposed from the resin (50). A lower surface (S1) of the second frame (20) and a second side surface (S2) of the second frame, the second side surface being far from the first frame (30) in the first direction (X), are exposed from the resin (50).

The embodiments are not limited to those described in the above, and various modifications can be made.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first frame;
a second frame arranged so as to face the first frame in a first direction and having a stepped portion on an end portion of an upper surface, the end portion being closer to the first frame;
a first semiconductor chip arranged on a bottom surface of the stepped portion of the second frame;
a wire configured to electrically couple the first semiconductor chip and the first frame; and
a resin configured to cover part of each of the first frame and the second frame, and to seal the first semiconductor chip and the wire,
wherein a lower surface of the first frame and a first side surface of the first frame, the first side surface being far from the second frame in the first direction, are exposed from the resin, and
a lower surface of the second frame and a second side surface of the second frame, the second side surface being far from the first frame in the first direction, are exposed from the resin.

2. The device according to claim 1, wherein
a height of the stepped portion of the second frame is equal to or smaller than ½ of a height of the second side surface of the second frame.

3. The device according to claim 1, wherein
an area of contact between the first semiconductor chip and the bottom surface of the stepped portion of the second frame is equal to or greater than ½ of an area of a lower surface of the first semiconductor chip.

4. The device according to claim 1, wherein
part of the first semiconductor chip faces the second frame.

5. The device according to claim 4, wherein
the stepped portion of the second frame has a first side wall in the first direction, and a second side wall and a third side wall which face each other in a second direction intersecting the first direction, and
three side surfaces of the first semiconductor chip are surrounded by the first to third side walls.

6. The device according to claim 4, wherein
the stepped portion of the second frame has a first side wall in the first direction, and
the first semiconductor chip faces the first side wall in the first direction.

7. The device according to claim 6, wherein
the bottom surface of the stepped portion of the second frame has two grooves, and
the first semiconductor chip is arranged between the two grooves.

8. The device according to claim 7, wherein
each of the two grooves extends from the first side wall to an end portion of the bottom surface of the stepped portion in the first direction, the end portion being closer to the first frame, and
the two grooves are spaced apart from each other in a second direction intersecting the first direction.

9. The device according to claim 7, wherein
each of the two grooves is formed into a letter V shape as viewed in the first direction.

10. The device according to claim 1, wherein
the first frame includes a first base portion and a first projecting portion,
the first projecting portion projects from the first base portion to a side far from the second frame in the first direction and has a first notch portion on an end portion of a lower surface, the end portion being not in contact with the first base portion,
the second frame includes a second base portion and a second projecting portion,
the second projecting portion projects from the second base portion to a side far from the first frame in the first direction and has a second notch portion on an end portion of a lower surface, the end portion being not in contact with the second base portion, and
a lower surface of the first base portion, a lower surface of the first projecting portion, the first notch portion, a lower surface of the second base portion, a lower surface of the second projecting portion, and the second notch portion are provided with a plating layer.

11. The device according to claim 1, further comprising a second semiconductor chip,
wherein the first frame has a stepped portion on an end portion of an upper surface, the end portion being closer to the second frame,
the second semiconductor chip is arranged on a bottom surface of the stepped portion of the first frame, and
the wire electrically couples the first semiconductor chip and the first frame via the second semiconductor chip.

12. The device according to claim 11, wherein
a height of the stepped portion of the first frame is equal to or smaller than ½ of a height of the first side surface of the first frame.

13. The device according to claim 11, wherein
part of the second semiconductor chip faces the first frame.

14. The device according to claim 1, wherein
a height of the first side surface of the first frame and a height of the second side surface of the second frame are 150 μm or greater and 200 μm or smaller.

15. A method of manufacturing a semiconductor device, comprising:
forming a stepped portion on an end portion of an upper surface of a second base of a lead frame base including a first base and the second base arranged so as to face the first base in a first direction, the end portion being closer to the first base;
forming a first semiconductor chip on a bottom surface of the stepped portion of the second base;
coupling the first semiconductor chip and the first base by a wire;
covering part of each of the first base and the second base with a resin, and sealing the first semiconductor chip and the wire with the resin;
forming a plating layer on a lower surface and a side surface which are exposed from the resin of the first base, and a lower surface and a side surface which are exposed from the resin of the second base; and
dicing the lead frame base and the resin.

16. The method according to claim 15, wherein
the forming the stepped portion on the upper surface of the second base includes
half-etching the end portion of the upper surface of the second base, the end portion being closer to the first base.

17. The method according to claim 15, wherein
the forming the stepped portion on the upper surface of the second base includes forming the stepped portion having a first side wall in the first direction, and a second side wall and a third side wall which face each other in a second direction intersecting the first direction.

18. The method according to claim 15, wherein
the forming the stepped portion on the upper surface of the second base includes forming the stepped portion having a first side wall in the first direction.

19. The method according to claim 18, wherein
the forming the stepped portion on the upper surface of the second base further includes forming two grooves on the bottom surface of the stepped portion, and
the forming the first semiconductor chip includes forming the first semiconductor chip between the two grooves.

20. The method according to claim 19, wherein the forming the two grooves on the bottom surface of the stepped portion includes forming two grooves which are spaced apart from each other in a second direction intersecting the first direction and which each extend from the first side wall to an end portion of the bottom surface of the stepped portion in the first direction, the end portion being closer to the first base.
